(19) United States
(12) Patent Application Publication
(10) Pub. No.: US 2026/0282768 A1
(43) Pub. Date: Sep. 17, 2026

(54) MEMORY DEVICE

(71) Applicant: Kioxia Corporation, Tokyo (JP)

(72) Inventors: Dandan ZHAO, Yokohama (JP); Masakazu GOTO, Moriya (JP)

(73) Assignee: Kioxia Corporation, Tokyo (JP)

(21) Appl. No.: 19/322,818

(22) Filed: Sep. 9, 2025

(30) Foreign Application Priority Data
Mar. 13, 2025 (JP) 2025-039861

(51) Int. Cl. H10N 70/00; G11C 13/00; H10B 63/00

(52) U.S. Cl. CPC H10N 70/883; G11C 13/004; G11C 13/0069; H10B 63/80; H10N 70/8833

(57) ABSTRACT

A memory device of embodiments includes a memory cell including a first conductive layer, a memory layer, and a second conductive layer. The memory layer contains an oxide, a nitride, or an oxynitride of a first element selected from Al, Si, Ge, Zr, Y, Ta, La, Ce, Ti, Hf, and Mg, a second element selected from Al, Zn, Sn, Ga, Bi, and In, and a third element selected from Te, S, Se, and Sb. The memory layer includes a first region, a second region, and a third region. The sum of concentrations of second and third elements is greater in the first region than in the second region. In the third region, a concentration of the third element is higher than a concentration of the second element. The ratio of the concentration of the third element to the concentration of the second element is greater in the third region than in the second region.

### CROSS-REFERENCE TO RELATED APPLICATION

This application is based upon and claims the benefit of priority from Japanese Patent Application No. 2025-039861, filed on Mar. 13, 2025, the entire contents of which are incorporated herein by reference.

### FIELD

Embodiments described herein relate generally to a memory device.

### BACKGROUND

An example of a large-capacity nonvolatile memory device is a cross-point type two-terminal memory device. In the cross-point type two-terminal memory device, scaling-down and high integration of memory cells are easy.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is a diagram showing the distribution of the atomic concentrations of elements contained in the memory device according to the first embodiment;

FIG. 4 is an explanatory diagram of an example of the current-voltage characteristics of the memory device according to the first embodiment;

FIG. 5 is an explanatory diagram of a first operation example of a memory operation of the memory device according to the first embodiment;

FIG. 6 is an explanatory diagram of a problem of the memory device according to the first embodiment;

FIG. 7 is an explanatory diagram of a second operation example of the memory operation of the memory device according to the first embodiment;

FIG. 8 is a schematic cross-sectional view of a memory cell in a memory device according to a comparative example;

FIG. 9 is an explanatory diagram of an example of the current-voltage characteristics of a memory device according to the comparative example;

FIG. 10 is a schematic cross-sectional view of a memory cell in a memory device according to a first modification example of the first embodiment;

FIG. 11 is a schematic cross-sectional view of a memory cell in a memory device according to a second modification example of the first embodiment;

FIG. 12 is a schematic cross-sectional view of a memory cell in a memory device according to a third modification example of the first embodiment; and

FIG. 13 is a schematic cross-sectional view of a memory cell in a memory device according to a second embodiment.

### DETAILED DESCRIPTION

A memory device of embodiments includes a memory cell including a first conductive layer, a second conductive layer, and a memory layer provided between the first conductive layer and the second conductive layer. The memory layer contains an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg). The memory layer contains a second element being different from the first element, and being at least one element selected from a group consisting of aluminum (Al), zinc (Zn), tin (Sn), gallium (Ga), bismuth (Bi), and indium (In). The memory layer contains a third element being at least one element selected from a group consisting of tellurium (Te), sulfur(S), selenium (Se), and antimony (Sb). The memory layer includes a first region, a second region, and a third region, and the second region is provided between the first region and the third region. The first region contains the second element and the third element. The second region contains the oxide, the nitride, or the oxynitride of the first element, and contains the second element and the third element. The third region contains the third element and contains or does not contain the second element. A sum of an atomic concentration of the second element and an atomic concentration of the third element in the first region is greater than a sum of an atomic concentration of the second element and an atomic concentration of the third element in the second region. An atomic concentration of the third element in the third region is higher than an atomic concentration of the second element in the third region. A ratio of the atomic concentration of the third element to the atomic concentration of the second element in the third region is greater than a ratio of the atomic concentration of the third element to the atomic concentration of the second element in the second region.

Hereinafter, embodiments will be described with reference to the diagrams. In addition, in the following description, the same or similar members and the like are denoted by the same reference numerals, and the description of the members and the like once described will be omitted as appropriate.

For the qualitative analysis and quantitative analysis of the chemical composition forming the memory device in this specification, for example, Rutherford backscattering spectroscopy (RBS), secondary ion mass spectroscopy (SIMS), energy dispersive X-ray spectroscopy (EDS), and electron energy loss spectroscopy (EELS) can be used. In addition, when measuring the thickness of each member forming the memory device, a distance between members, and the like, for example, a transmission electron microscope (TEM) can be used. In addition, for example, X-ray photoelectron spectroscopy (XPS), X-ray absorption fine structure (XAFS), Raman spectroscopy (Raman), scanning transmission electron microscope (STEM), or EELS can be used to identify the constituent materials of each member forming the memory device, measure the abundance ratio of the constituent materials, identify the bonding state of the constituent materials, identify the local structure (atomic distance, coordination number) of the constituent materials, measure the chemical state of the constituent materials, and compare the concentrations of the constituent materials.

In this specification, the atomic concentration is expressed as an atomic composition percentage (at%).

### First Embodiment

A memory device according to a first embodiment includes a memory cell including a first conductive layer, a second conductive layer, and a memory layer provided between the first conductive layer and the second conductive layer. The memory layer contains an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg). The memory layer contains a second element being different from the first element, and being at least one element selected from a group consisting of aluminum (Al), zinc (Zn), tin (Sn), gallium (Ga), bismuth (Bi), and indium (In). The memory layer contains a third element being at least one element selected from a group consisting of tellurium (Te), sulfur (S), selenium (Se), and antimony (Sb). The memory layer includes a first region, a second region, and a third region, and the second region is provided between the first region and the third region. The first region contains the second element and the third element. The second region contains the oxide, the nitride, or the oxynitride of the first element, the second element, and the third element. The third region contains the third element and contains or does not contain the second element. A sum of an atomic concentration of the second element and an atomic concentration of the third element in the first region is greater than a sum of an atomic concentration of the second element and an atomic concentration of the third element in the second region. An atomic concentration of the third element in the third region is higher than an atomic concentration of the second element in the third region. A ratio of an atomic concentration of the third element to an atomic concentration of the second element in the third region is greater than a ratio of an atomic concentration of the third element to an atomic concentration of the second element in the second region.

In addition, the memory device according to the first embodiment further includes a plurality of first wirings and a plurality of second wirings crossing the plurality of first wirings. In addition, the memory cell is provided in a region where one of the plurality of first wirings and one of the plurality of second wirings cross each other.

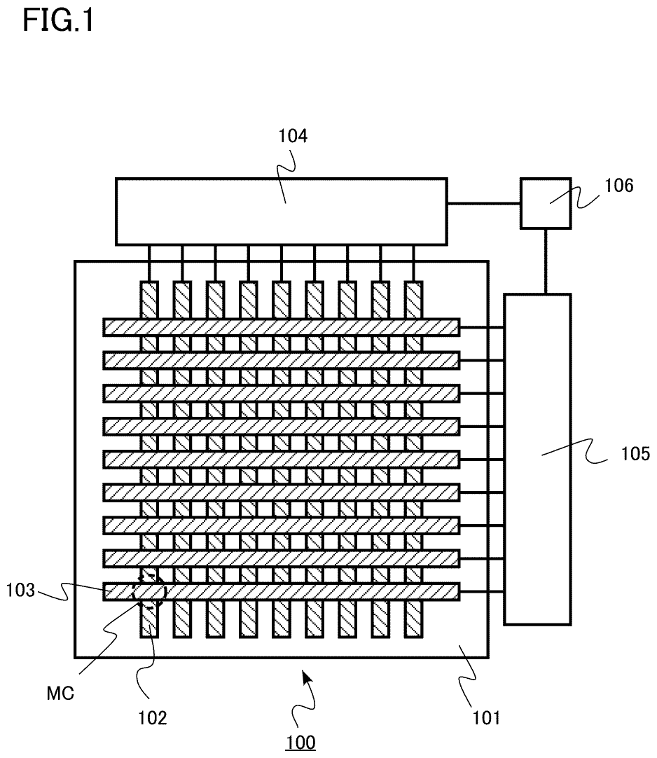

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal memory device having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current or the electric potential to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

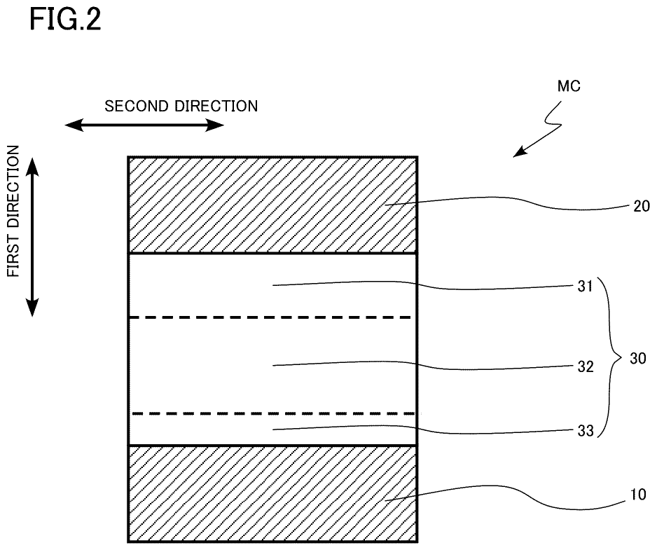

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1. FIG. 2 shows a cross section parallel to a first direction connecting a lower electrode 10 and an upper electrode 20.

As shown in FIG. 2, the memory cell MC includes the lower electrode 10, the upper electrode 20, and a memory layer 30. The memory layer 30 includes a first region 31, a second region 32, and a third region 33.

The lower electrode 10 is an example of the first conductive layer. The upper electrode 20 is an example of the second conductive layer. The lower electrode 10 is an example of the other conductive layer. The upper electrode 20 is an example of one of the conductive layers.

The memory cell MC has a function of storing information and also has a switching function.

The lower electrode 10 is connected to the word line 102. The lower electrode 10 is, for example, a metal. The lower electrode 10 contains, for example, at least one material selected from a group consisting of carbon, carbon nitride, tungsten, tungsten carbide, tungsten nitride, titanium, titanium nitride, tantalum, tantalum carbide, and tantalum nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of carbon, carbon nitride, tungsten, tungsten carbide, tungsten nitride, titanium, titanium nitride, tantalum, tantalum carbide, and tantalum nitride. The upper electrode 20 may be a part of the bit line 103.

The memory layer 30 is provided between the lower electrode 10 and the upper electrode 20. The thickness of the memory layer 30 in a first direction from the lower electrode 10 to the upper electrode 20 is, for example, equal to or more than 4 nm and equal to or less than 50 nm. The length of the memory layer 30 in a second direction perpendicular to the first direction is, for example, equal to or more than 10 nm and equal to or less than 50 nm.

The memory layer 30 has a nonlinear current-voltage characteristic that a current increases abruptly at a specific threshold voltage. In addition, the memory layer 30 has a characteristic that the threshold voltage changes with the application of a predetermined voltage.

The memory layer 30 contains an oxide, a nitride, or an oxynitride of a first element. The memory layer 30 contains a second element and a third element. The memory layer 30 contains at least one of oxygen (O) and nitrogen (N).

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg).

The oxide of the first element is, for example, an aluminum oxide, a silicon oxide, a germanium oxide, a zirconium oxide, a yttrium oxide, a tantalum oxide, a lanthanum oxide, a cerium oxide, a titanium oxide, a hafnium oxide, or a magnesium oxide. The nitride of the first element is, for example, an aluminum nitride, a silicon nitride, a germanium nitride, a zirconium nitride, a yttrium nitride, a tantalum nitride, a lanthanum nitride, a cerium nitride, a titanium nitride, a hafnium nitride, or a magnesium nitride. The oxynitride of the first element is, for example, an aluminum oxynitride, a silicon oxynitride, a germanium oxynitride, a zirconium oxynitride, a yttrium oxynitride, a tantalum oxynitride, a lanthanum oxynitride, a cerium oxynitride, a titanium oxynitride, a hafnium oxynitride, or a magnesium oxynitride.

The second element is an element different from the first element. The second element is at least one element selected from a group consisting of aluminum (Al), zinc (Zn), tin (Sn), gallium (Ga), bismuth (Bi), and indium (In). The third element is at least one element selected from a group consisting of tellurium (Te), sulfur(S), selenium (Se), and antimony (Sb).

The memory layer 30 contains, for example, a compound of the second element and the third element. Examples of the compound of the second element and the third element include aluminum telluride, zinc telluride, tin telluride, gallium telluride, bismuth telluride, indium telluride, aluminum sulfide, zinc sulfide, tin sulfide, gallium sulfide, bismuth sulfide, indium sulfide, aluminum selenide, zinc selenide, tin selenide, gallium selenide, bismuth selenide, indium selenide, aluminum antimonide, zinc antimonide, tin antimonide, gallium antimonide, bismuth antimonide, and indium antimonide.

The memory layer 30 includes the first region 31, the second region 32, and the third region 33. The second region 32 is provided between the first region 31 and the third region 33. For example, the first region 31 and the second region 32 are in contact with each other. For example, the third region 33 and the second region 32 are in contact with each other.

The first region 31 is provided between the second region 32 and the upper electrode 20. The first region 31 is in contact with, for example, the upper electrode 20.

The third region 33 is provided between the second region 32 and the lower electrode 10. The third region 33 is in contact with, for example, the lower electrode 10.

The first region 31 contains the second element and the third element. The first region 31 may or may not contain an oxide, a nitride, or an oxynitride of the first element.

The second region 32 contains an oxide, a nitride, or an oxynitride of the first element, the second element, and the third element.

The third region 33 contains the third element. The third region 33 may or may not contain the second element. The third region 33 may or may not contain an oxide, a nitride, or an oxynitride of the first element.

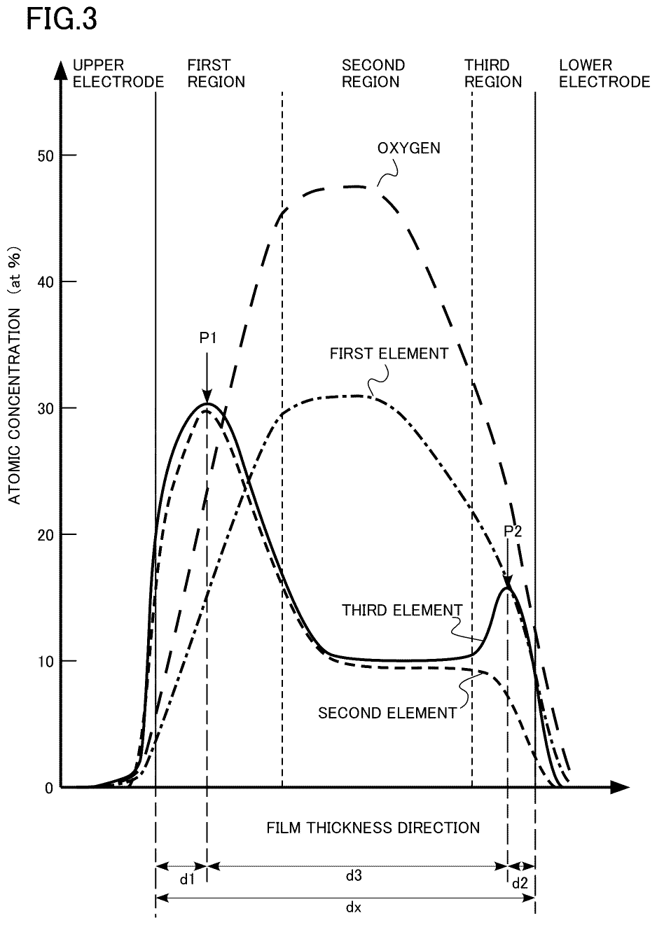

FIG. 3 is a diagram showing the distribution of the atomic concentrations of elements contained in the memory device according to the first embodiment. FIG. 3 shows the distribution of the atomic concentration of elements in the film thickness direction. The film thickness direction is the first direction. FIG. 3 illustrates a case where the memory layer 30 contains an oxide of the first element.

For example, in the analysis of chemical composition using TEM and EDS or EELS, an electron beam acceleration voltage of 200 kV, a beam current of 100 pA to 1 nA, and a beam diameter for a spatial resolution of about 1 nm are applied as the TEM conditions. For example, by continuously measuring the chemical compositions of the upper electrode 20, the memory layer 30, and the lower electrode 10 at intervals equal to or less than 1 nm in the film thickness direction of the memory layer 30 of the measurement sample using the above TEM conditions, the distribution of the atomic concentrations of the elements shown in FIG. 3 can be obtained.

The sum of the atomic concentration of the first element, the atomic concentration of the second element, the atomic concentration of the third element, the atomic concentration of oxygen (O), and the atomic concentration of nitrogen (N) in the memory layer 30 is referred to as a total concentration. The total concentration in the memory layer 30 is, for example, equal to or more than 80 at % and equal to or less than 100 at %.

The sum of the atomic concentration of the second element and the atomic concentration of the third element in the first region 31 is greater than the sum of the atomic concentration of the second element and the atomic concentration of the third element in the second region 32. For example, the sum of the atomic concentration of the second element and the atomic concentration of the third element in the first region 31 is equal to or more than twice and equal to or less than 5 times the sum of the atomic concentration of the second element and the atomic concentration of the third element in the second region 32.

The atomic concentration of the third element in the third region 33 is higher than the atomic concentration of the second element in the third region 33. For example, the atomic concentration of the third element in the third region 33 is equal to or more than 1.2 times and equal to or less than 10 times the atomic concentration of the second element in the third region 33.

The ratio of the atomic concentration of the third element to the atomic concentration of the second element in the third region 33 (atomic concentration of the third element/atomic concentration of the second element) is greater than the ratio of the atomic concentration of the third element to the atomic concentration of the second element in the second region 32. The ratio of the atomic concentration of the third element to the atomic concentration of the second element in the second region 32 is, for example, equal to or more than 0.3 and equal to or less than 2.

The ratio of the atomic concentration of the third element to the atomic concentration of the second element in the third region 33 is, for example, greater than the ratio of the atomic concentration of the third element to the atomic concentration of the second element in the first region 31. The ratio of the atomic concentration of the third element to the atomic concentration of the second element in the first region 31 is, for example, equal to or more than 0.3 and equal to or less than 2.

The atomic concentration of the third element in the first region 31 is, for example, higher than the atomic concentration of the third element in the third region 33. The atomic concentration of the third element in the first region 31 is, for example, equal to or more than 1.5 times and equal to or less than 5 times the atomic concentration of the third element in the third region 33.

The atomic concentration of the third element in the third region 33 is, for example, higher than the atomic concentration of the third element in the second region 32. The atomic concentration of the third element in the third region 33 is, for example, equal to or more than 1.2 times and equal to or less than 3 times the atomic concentration of the third element in the second region 32.

The ratio of the sum of the atomic concentration of the first element, the atomic concentration of oxygen (O), and the atomic concentration of nitrogen (N) to the total concentration in the first region 31 is, for example, less than 50%. The ratio of the sum of the atomic concentration of the first element, the atomic concentration of oxygen (O), and the atomic concentration of nitrogen (N) to the total concentration in the second region 32 is, for example, equal to or more than 50% and equal to or less than 95%.

The ratio of the sum of the atomic concentration of the second element and the atomic concentration of the third element to the total concentration in the first region 31 is, for example, equal to or more than 50% and equal to or less than 100%. The ratio of the sum of the atomic concentration of the second element and the atomic concentration of the third element to the total concentration in the second region 32 is, for example, equal to or more than 5% and less than 50%.

The ratio of the atomic concentration of the third element to the total concentration in the third region 33 is, for example, equal to or more than 10% and equal to or less than 100%.

As shown in FIG. 3, the distribution of the atomic concentration of the third element in the first direction (film thickness direction) from the upper electrode 20 to the lower electrode 10 has a first peak (P1 in FIG. 3) in the first region 31 and a second peak (P2 in FIG. 3) in the third region 33.

A first distance (d1 in FIG. 3) from the upper electrode 20 to the first peak P1 in the first direction is greater than a second distance (d2 in FIG. 3) from the lower electrode 10 to the second peak P2 in the first direction.

The second distance d2 is, for example, equal to or less than one-fourth of the distance (dx in FIG. 3) between the upper electrode 20 and the lower electrode 10 in the first direction.

A third distance (d3 in FIG. 3) from the first peak P1 to the second peak P2 in the first direction is, for example, equal to or more than one-third and equal to or less than three-quarters of the distance dx in the first direction between the upper electrode 20 and the lower electrode 10.

In addition, when deriving the first distance d1, the second distance d2, or the distance dx, the boundary between the upper electrode 20 and the first region 31 or the boundary between the lower electrode 10 and the third region 33 can be determined, for example, by the following method. The distribution of the atomic concentrations of elements forming the electrode in the first direction (film thickness direction) from the upper electrode 20 to the lower electrode 10 is acquired. Then, a position where the distribution of the atomic concentrations of elements forming the electrode crosses the distribution of the atomic concentration of the third element is defined as the boundary between the upper electrode 20 and the first region 31 or the boundary between the lower electrode 10 and the third region 33.

For example, when the upper electrode 20 and the lower electrode 10 are formed of carbon (C) and the third element is tellurium (Te), a position on the upper electrode 20 side, of the two positions where the distribution of the atomic concentration of carbon (C) and the atomic concentration of tellurium (Te) cross each other, is defined as the boundary between the upper electrode 20 and the first region 31, and a position on the lower electrode 10 side is defined as the boundary between the lower electrode 10 and the third region 33.

Next, the function and effect of the memory device according to the first embodiment will be described.

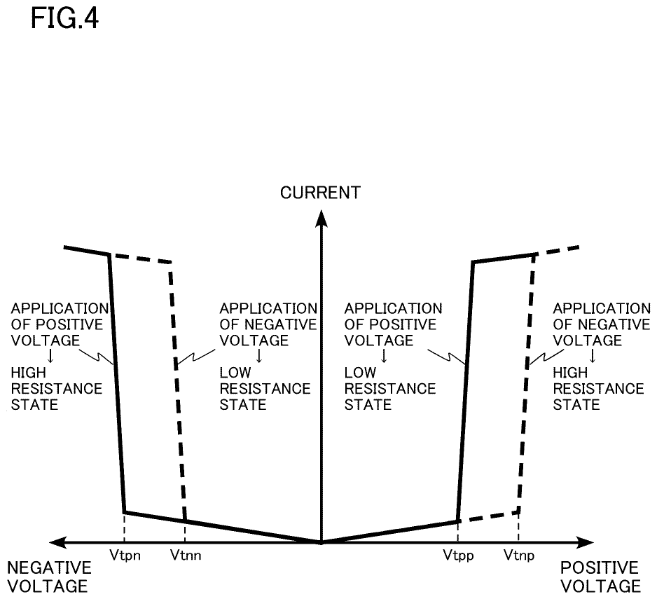

FIG. 4 is an explanatory diagram of an example of the current-voltage characteristics of the memory device according to the first embodiment. The horizontal axis indicates a voltage applied to the memory cell MC in the first embodiment, and the vertical axis indicates a current flowing through the memory cell MC. In FIG. 4, the horizontal axis indicates a voltage applied to the upper electrode 20 with the electric potential of the lower electrode 10 as a reference.

FIG. 4 shows an example of the current-voltage characteristics when the upper electrode 20 and the lower electrode 10 are formed of carbon (C) and the memory layer 30 contains an oxide of aluminum (Al), zinc (Zn), and tellurium (Te). FIG. 4 shows an example of the current-voltage characteristics when the first element is aluminum (Al), the second element is zinc (Zn), and the third element is tellurium (Te).

The memory cell MC shows different current-voltage characteristics when a predetermined positive voltage is applied to the upper electrode 20 and when a predetermined negative voltage is applied to the upper electrode 20. In FIG. 4, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory cell MC can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

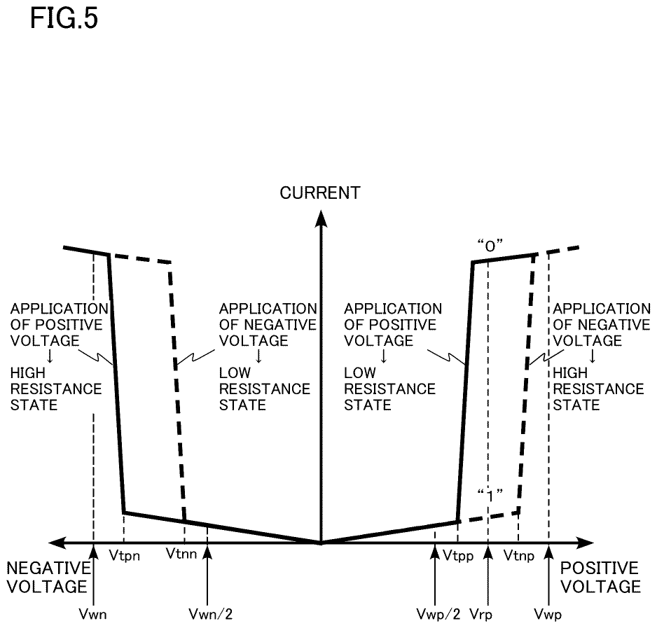

FIG. 5 is an explanatory diagram of a first operation example of the memory operation of the memory device according to the first embodiment. FIG. 5 shows a positive write voltage Vwp, half (Vwp/2) of the positive write voltage Vwp, a negative write voltage Vwn, half (Vwn/2) of the negative write voltage Vwn, and a positive read voltage Vrp when performing a memory operation.

In the first operation example, the high resistance state and the low resistance state on the positive voltage side are used for the memory operation. In the first operation example, the positive read voltage Vrp is used as a read voltage.

When writing data “1” to the memory cell MC, the negative write voltage Vwn is applied to the upper electrode 20. The negative write voltage Vwn is a voltage lower than the first negative voltage side threshold voltage Vtpn. By applying the negative write voltage Vwn to the upper electrode 20, a high resistance state is realized on the positive voltage side, and data “1” is written to the memory cell MC.

When writing data “0” to the memory cell MC, the positive write voltage Vwp is applied to the upper electrode 20. The positive write voltage Vwp is a voltage higher than the second positive voltage side threshold voltage Vtnp. By applying the positive write voltage Vwp to the upper electrode 20, a low resistance state is realized on the positive voltage side, and data “0” is written to the memory cell MC.

When reading data from the memory cell MC, the positive read voltage Vrp is applied to the memory cell MC. The data in the memory cell MC can be determined by detecting a current change or an electric potential change caused by the difference between a current that flows when data is “1” and a current that flows when data is “0”.

In addition, in the case of the first operation example, regardless of whether the data in the memory cell MC is data “1” or data “0”, the application of the positive read voltage Vrp does not destroy the data. In other words, in the case of the first operation example, non-destructive reading is possible regardless of whether the data of the selected cell is data “1” or data “0”.

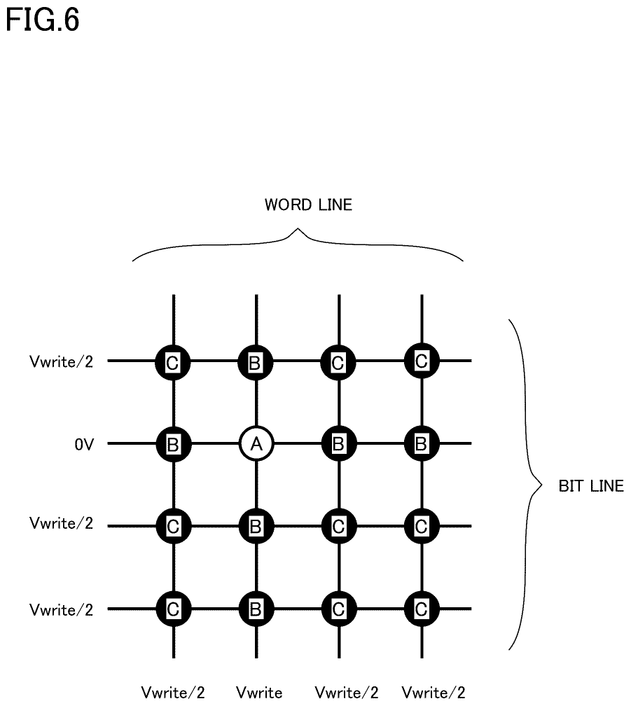

FIG. 6 is an explanatory diagram of a problem of the memory device according to the first embodiment. FIG. 6 shows an example of a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (non-selected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, in the first operation example, as shown in FIG. 5, when the positive write voltage Vwp is applied to the selected cell, a voltage Vwp/2 is applied to the half-selected cell. In addition, when the negative write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory cell MC also functions as a switching element. The memory cell MC has a function of storing information and also has a switching function.

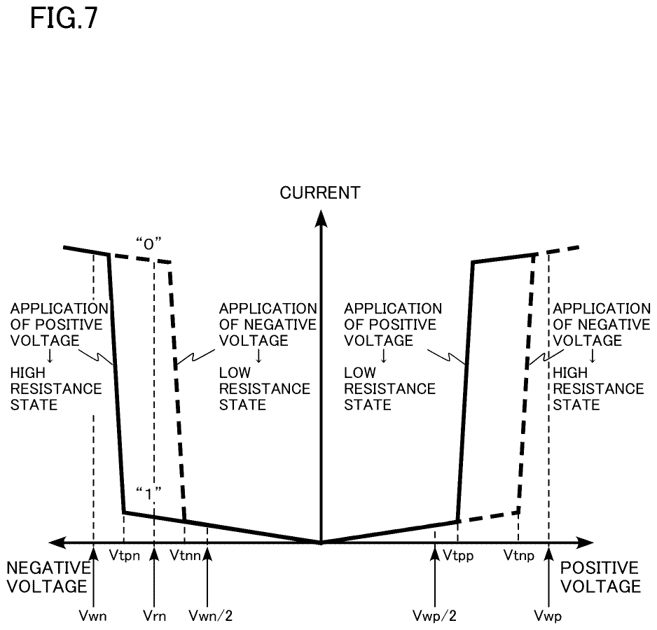

FIG. 7 is an explanatory diagram of a second operation example of the memory operation of the memory device according to the first embodiment. FIG. 7 shows a positive write voltage Vwp, half (Vwp/2) the positive write voltage Vwp, a negative write voltage Vwn, half (Vwn/2) the negative write voltage Vwn, and a negative read voltage Vrn when performing a memory operation.

In the second operation example, the high resistance state and the low resistance state on the negative voltage side are used for memory operation. In the second operation example, the negative read voltage Vrn is used as a read voltage.

When writing data “1” to the memory cell MC, the positive write voltage Vwp is applied to the upper electrode 20. The positive write voltage Vwp is a voltage higher than the second positive voltage side threshold voltage Vtnp. By applying the positive write voltage Vwp to the upper electrode 20, a high resistance state is realized on the negative voltage side, and data “1” is written to the selected cell.

When writing data “0” to the memory cell MC, the negative write voltage Vwn is applied to the upper electrode 20. The negative write voltage Vwn is a voltage lower than the first negative voltage side threshold voltage Vtpn. By applying the negative write voltage Vwn to the upper electrode 20, a low resistance state is realized on the negative voltage side, and data “0” is written to the selected cell.

When reading data from the memory cell MC, the negative read voltage Vrn is applied to the memory cell MC. The data in the memory cell MC can be determined by detecting a current change or an electric potential change caused by the difference between a current that flows when data is “1” and a current that flows when data is “0”.

In addition, in the case of the second operation example, regardless of whether the data in the memory cell MC is data “1” or data “0”, the application of the negative read voltage Vrn does not destroy the data. In other words, in the case of the second operation example, non-destructive reading is possible regardless of whether the data in the memory cell MC is data “1” or data “0”.

In the second operation example, as shown in FIG. 7, as in the first operation example, when the positive write voltage Vwp is applied to the selected cell, the voltage Vwp/2 is applied to the half-selected cell. In addition, when the negative write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory cell MC also functions as a switching element. The memory cell MC has a function of storing information and also has a switching function.

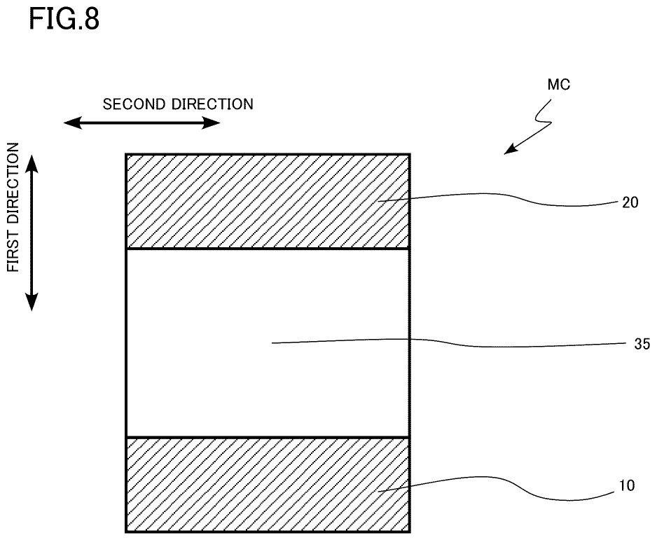

FIG. 8 is a schematic cross-sectional view of a memory cell in a memory device according to a comparative example. FIG. 8 is a diagram corresponding to FIG. 2 in the first embodiment.

The memory cell MC in the comparative example is different from the memory cell MC in the first embodiment in that the memory layer 35 does not include the first region 31, the second region 32, and the third region 33.

The memory cell MC in the comparative example contains an oxide, a nitride, or an oxynitride of the first element. The memory layer 35 contains the second element and the third element. The memory layer 35 contains at least one of oxygen (O) and nitrogen (N). For example, the entire memory layer 35 has a configuration similar to that of the second region 32 of the memory layer 30 in the first embodiment.

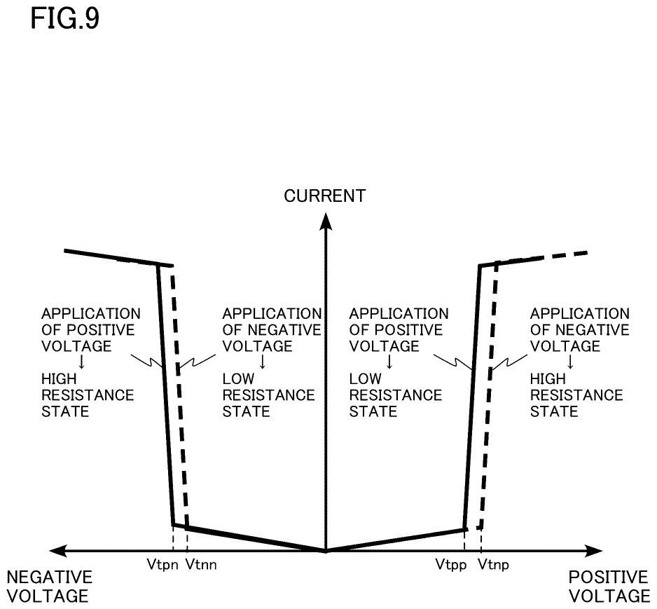

FIG. 9 is an explanatory diagram of an example of the current-voltage characteristics of the memory device according to the comparative example. FIG. 9 is a diagram corresponding to FIG. 4 in the first embodiment.

As is apparent from the comparison between FIGS. 4 and 9, the difference between the first positive voltage side threshold voltage Vtpp and the second positive voltage side threshold voltage Vtnp of the memory cell MC in the comparative example is smaller than the difference between the first positive voltage side threshold voltage Vtpp and the second positive voltage side threshold voltage Vtnp of the memory cell MC in the first embodiment. When the positive read voltage Vrp is used as a read voltage as in the first operation example of the first embodiment, the positive read voltage Vrp needs to be set to a voltage between the first positive voltage side threshold voltage Vtpp and the second positive voltage side threshold voltage Vtnp. If the difference between the first positive voltage side threshold voltage Vtpp and the second positive voltage side threshold voltage Vtnp is small, an error in reading data from the memory cell MC is likely to occur. In other words, the memory window of the memory cell MC is narrowed.

In the memory cell MC in the first embodiment, since the memory layer 30 has three regions, that is, the first region 31, the second region 32, and the third region 33, the difference between the first positive voltage side threshold voltage Vtpp and the second positive voltage side threshold voltage Vtnp is large. Therefore, an error in reading data from the memory cell MC is less likely to occur. In other words, the memory window of the memory cell MC is widened.

As is apparent from the comparison between FIGS. 4 and 9, the difference between the first negative voltage side threshold voltage Vtpn and the second negative voltage side threshold voltage Vtnn of the memory cell MC in the comparative example is smaller than the difference between the first negative voltage side threshold voltage Vtpn and the second negative voltage side threshold voltage Vtnn of the memory cell MC in the first embodiment. When the negative read voltage Vrn is used as a read voltage as in the second operation example, the negative read voltage Vrn needs to be set to a voltage between the first negative voltage side threshold voltage Vtpn and the second negative voltage side threshold voltage Vtnn. If the difference between the first negative voltage side threshold voltage Vtpn and the second negative voltage side threshold voltage Vtnn is small, an error in reading data from the memory cell MC is likely to occur. In other words, the memory window of the memory cell MC is narrowed.

In the memory cell MC in the first embodiment, since the memory layer 30 has three regions, that is, the first region 31, the second region 32, and the third region 33, the difference between the first negative voltage side threshold voltage Vtpn and the second negative voltage side threshold voltage Vtnn is large. Therefore, an error in reading data from the memory cell MC is less likely to occur. In other words, the memory window of the memory cell MC is widened.

From the viewpoint of widening the memory window of the memory cell MC, the sum of the atomic concentration of the second element and the atomic concentration of the third element in the first region 31 is preferably equal to or more than twice the sum of the atomic concentration of the second element and the atomic concentration of the third element in the second region 32, and more preferably equal to or more than three times the sum of the atomic concentration of the second element and the atomic concentration of the third element in the second region 32.

From the viewpoint of widening the memory window of the memory cell MC, the atomic concentration of the third element in the third region 33 is preferably equal to or more than 1.2 times the atomic concentration of the second element in the third region 33, and more preferably equal to or more than 1.5 times the atomic concentration of the second element in the third region 33.

From the viewpoint of widening the memory window of the memory cell MC, the atomic concentration of the third element in the first region 31 is preferably higher than the atomic concentration of the third element in the third region 33. The atomic concentration of the third element in the first region 31 is preferably equal to or more than 1.5 times the atomic concentration of the third element in the third region 33, and more preferably equal to or more than twice the atomic concentration of the third element in the third region 33.

From the viewpoint of widening the memory window of the memory cell MC, the atomic concentration of the third element in the third region 33 is preferably higher than the atomic concentration of the third element in the second region 32. The atomic concentration of the third element in the third region 33 is preferably equal to or more than 1.2 times the atomic concentration of the third element in the second region 32, and more preferably equal to or more than 1.5 times the atomic concentration of the third element in the second region 32.

From the viewpoint of widening the memory window of the memory cell MC, the ratio of the atomic concentration of the third element to the atomic concentration of the second element in the second region 32 is preferably equal to or more than 0.3 and equal to or less than 2.

From the viewpoint of widening the memory window of the memory cell MC, the ratio of the sum of the atomic concentration of the first element, the atomic concentration of oxygen (O), and the atomic concentration of nitrogen (N) to the total concentration in the first region 31 is preferably less than 50%, more preferably equal to or less than 40%, and even more preferably equal to or less than 30%, for example.

From the viewpoint of widening the memory window of the memory cell MC, the ratio of the sum of the atomic concentration of the first element, the atomic concentration of oxygen (O), and the atomic concentration of nitrogen (N) to the total concentration in the second region 32 is preferably equal to or more than 50%, more preferably equal to or more than 60%, and even more preferably equal to or more than 70%.

From the viewpoint of widening the memory window of the memory cell MC, the ratio of the sum of the atomic concentration of the second element and the atomic concentration of the third element to the total concentration in the first region 31 is preferably equal to or more than 50%, more preferably equal to or more than 60%, and even more preferably equal to or more than 70%.

From the viewpoint of widening the memory window of the memory cell MC, the ratio of the sum of the atomic concentration of the second element and the atomic concentration of the third element to the total concentration in the second region 32 is preferably less than 50%, more preferably equal to or less than 40%, and even more preferably equal to or less than 30%.

From the viewpoint of widening the memory window of the memory cell MC, the ratio of the atomic concentration of the third element to the total concentration in the third region 33 is preferably equal to or more than 10%, more preferably equal to or more than 20%, and even more preferably equal to or more than 30%.

From the viewpoint of widening the memory window of the memory cell MC, it is preferable that the distribution of the atomic concentration of the third element in the first direction (film thickness direction) from the upper electrode 20 to the lower electrode 10 has the first peak (P1 in FIG. 3) in the first region 31 and the second peak (P2 in FIG. 3) in the third region 33.

From the viewpoint of widening the memory window of the memory cell MC, it is preferable that the first distance (d1 in FIG. 3) from the upper electrode 20 to the first peak P1 in the first direction is greater than the second distance (d2 in FIG. 3) from the lower electrode 10 to the second peak P2 in the first direction.

From the viewpoint of widening the memory window of the memory cell MC, it is preferable that the second distance d2 is equal to or less than one-fourth of the distance (dx in FIG. 3) between the upper electrode 20 and the lower electrode 10 in the first direction, for example.

From the viewpoint of widening the memory window of the memory cell MC, it is preferable that the third distance (d3 in FIG. 3) from the first peak P1 to the second peak P2 in the first direction is equal to or more than one-third and equal to or less than three-quarters of the distance dx between the upper electrode 20 and the lower electrode 10 in the first direction, for example.

As described above, according to the first embodiment, since the memory window of the memory cell MC is widened, it is possible to realize a two-terminal memory device with excellent characteristics.

### First Modification Example

A memory device according to a first modification example of the first embodiment is different from the memory device according to the first embodiment in that the first conductive layer includes a first portion and a second portion and the first portion contains at least one element selected from hafnium (Hf), aluminum (Al), magnesium (Mg), zirconium (Zr), and titanium (Ti).

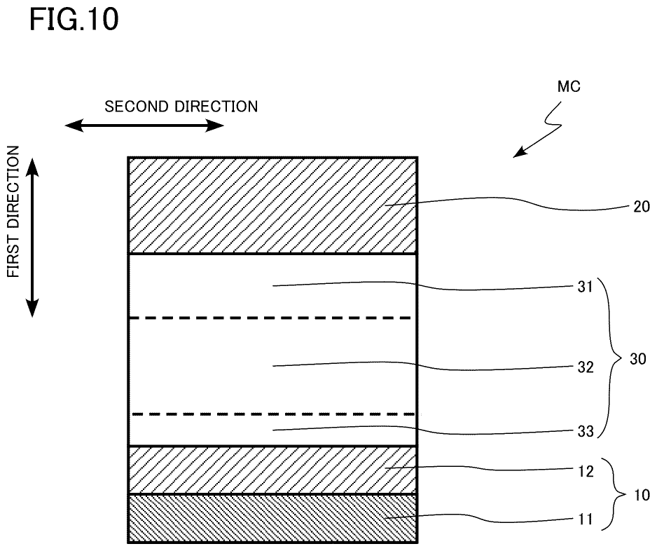

FIG. 10 is a schematic cross-sectional view of a memory cell in the memory device according to the first modification example of the first embodiment. FIG. 10 is a diagram corresponding to FIG. 2 in the first embodiment.

The lower electrode 10 includes a first portion 11 and a second portion 12. The second portion 12 is provided between the first portion 11 and the memory layer 30.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, aluminum magnesium boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

In the memory device according to the first modification example of the first embodiment, since the first portion 11 of the lower electrode 10 contains at least one element selected from hafnium (Hf), aluminum (Al), magnesium (Mg), zirconium (Zr), and titanium (Ti), degradation of the characteristics of the memory layer 30 is suppressed. In addition, since the first portion 11 is not in contact with the memory layer 30, desorption of oxygen (O) from the memory layer 30 is suppressed and accordingly, degradation of the characteristics of the memory layer 30 is suppressed.

As described above, according to the first modification example of the first embodiment, it is possible to realize a two-terminal memory device with excellent characteristics as in the first embodiment.

### Second Modification Example

A memory device according to a second modification example of the first embodiment is different from the memory device according to the first embodiment in that the first conductive layer includes a first portion and a second portion, the first portion contains at least one element selected from hafnium (Hf), aluminum (Al), magnesium (Mg), zirconium (Zr), and titanium (Ti), the second conductive layer includes a third portion and a fourth portion, and the fourth portion contains at least one element selected from hafnium (Hf), aluminum (Al), magnesium (Mg), zirconium (Zr), and titanium (Ti).

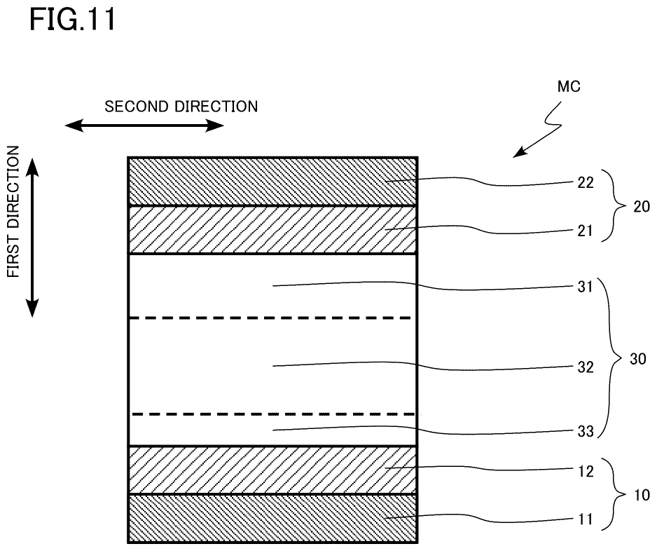

FIG. 11 is a schematic cross-sectional view of a memory cell in the memory device according to the second modification example of the first embodiment. FIG. 11 is a diagram corresponding to FIG. 2 in the first embodiment.

The lower electrode 10 includes a first portion 11 and a second portion 12. The second portion 12 is provided between the first portion 11 and the memory layer 30.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 includes a third portion 21 and a fourth portion 22. The third portion 21 is provided between the fourth portion 22 and the memory layer 30.

The third portion 21 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 22 contains at least one element selected from hafnium (Hf), aluminum (Al), magnesium (Mg), zirconium (Zr), and titanium (Ti). The fourth portion 22 contains, for example, borides of the above elements. The fourth portion 22 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10 and the fourth portion 22 of the upper electrode 20 contain at least one element selected from hafnium (Hf), aluminum (Al), magnesium (Mg), zirconium (Zr), and titanium (Ti), degradation of the characteristics of the memory layer 30 is suppressed. In addition, since the first portion 11 of the lower electrode 10 and the fourth portion 22 of the upper electrode 20 are not in contact with the memory layer 30, desorption of oxygen (O) from the memory layer 30 is suppressed and accordingly, degradation of the characteristics of the memory layer 30 is suppressed.

As described above, according to the second modification example of the first embodiment, it is possible to realize a two-terminal memory device with excellent characteristics as in the first embodiment.

### Third Modification Example

A memory device according to a third modification example of the first embodiment is different from the memory device according to the first embodiment in that the first conductive layer includes a first portion, a second portion, and a fifth portion, the first portion contains at least one element selected from hafnium (Hf), aluminum (Al), magnesium (Mg), zirconium (Zr), and titanium (Ti), the second conductive layer includes a third portion and a fourth portion, and the fourth portion contains at least one element selected from hafnium (Hf), aluminum (Al), magnesium (Mg), zirconium (Zr), and titanium (Ti).

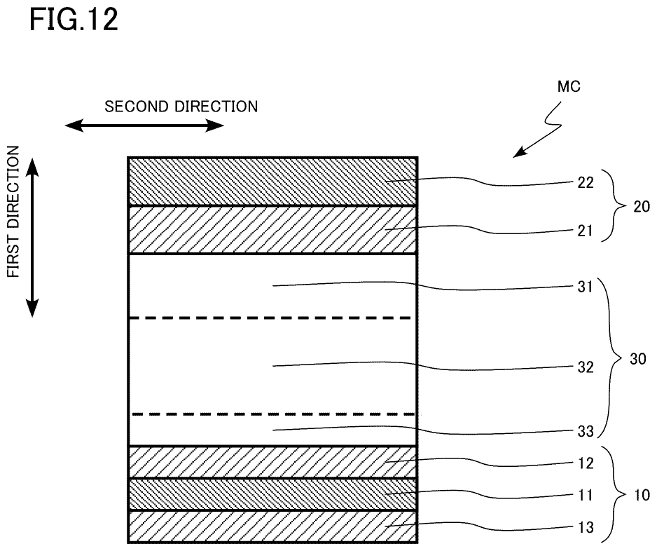

FIG. 12 is a schematic cross-sectional view of a memory cell in the memory device according to the third modification example of the first embodiment. FIG. 12 is a diagram corresponding to FIG. 2 in the first embodiment.

The lower electrode 10 includes a first portion 11, a second portion 12, and a fifth portion 13. The second portion 12 is provided between the first portion 11 and the memory layer 30. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of carbon, carbon nitride, tungsten, tungsten carbide, tungsten nitride, titanium, titanium nitride, tantalum, tantalum carbide, and tantalum nitride.

The upper electrode 20 includes a third portion 21 and a fourth portion 22. The third portion 21 is provided between the fourth portion 22 and the memory layer 30.

The third portion 21 contains, for example, at least one material selected from a group consisting of carbon, carbon nitride, tungsten, tungsten carbide, tungsten nitride, titanium, titanium nitride, tantalum, tantalum carbide, and tantalum nitride.

The fourth portion 22 contains at least one element selected from hafnium (Hf), aluminum (Al), magnesium (Mg), zirconium (Zr), and titanium (Ti). The fourth portion 22 contains, for example, borides of the above elements. The fourth portion 22 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10 and the fourth portion 22 of the upper electrode 20 contain at least one element selected from hafnium (Hf), aluminum (Al), magnesium (Mg), zirconium (Zr), and titanium (Ti), degradation of the characteristics of the memory layer 30 is suppressed. In addition, since the first portion 11 of the lower electrode 10 and the fourth portion 22 of the upper electrode 20 are not in contact with the memory layer 30, desorption of oxygen (O) from the memory layer 30 is suppressed and accordingly, degradation of the characteristics of the memory layer 30 is suppressed.

As described above, according to the third modification example of the first embodiment, it is possible to realize a two-terminal memory device with excellent characteristics as in the first embodiment.

As described above, according to the first embodiment and its modification examples, since the memory window of the memory cell MC is widened, it is possible to realize a two-terminal memory device with excellent characteristics.

### Second Embodiment

A memory device according to a second embodiment is different from the memory device according to the first embodiment in that the first region is provided between the second region and the first conductive layer and the third region is provided between the second region and the second conductive layer. Hereinafter, the description of a part of the content overlapping the first embodiment may be omitted.

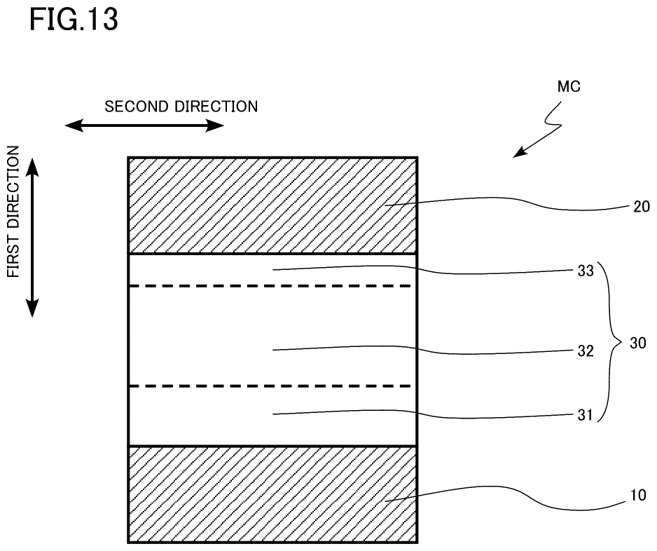

FIG. 13 is a schematic cross-sectional view of a memory cell in the memory device according to the second embodiment. FIG. 13 is a diagram corresponding to FIG. 2 in the first embodiment.

As shown in FIG. 13, the memory cell MC includes a lower electrode 10, an upper electrode 20, and a memory layer 30. The memory layer 30 includes a first region 31, a second region 32, and a third region 33.

The second region 32 is provided between the first region 31 and the third region 33. For example, the first region 31 and the second region 32 are in contact with each other. For example, the third region 33 and the second region 32 are in contact with each other.

The first region 31 is provided between the second region 32 and the lower electrode 10. The first region 31 is in contact with, for example, the lower electrode 10.

The third region 33 is provided between the second region 32 and the upper electrode 20. The third region 33 is in contact with, for example, the upper electrode 20.

The lower electrode 10 is an example of the first conductive layer. The upper electrode 20 is an example of the second conductive layer. The lower electrode 10 is an example of one of the conductive layers. The upper electrode 20 is an example of the other conductive layer.

As described above, according to the second embodiment, as in the first embodiment, since the memory window of the memory cell MC is widened, it is possible to realize a two-terminal memory device with excellent characteristics.

In the first embodiment, the case where the first positive voltage side threshold voltage Vtpp is lower than the second positive voltage side threshold voltage Vtnp and the first negative voltage side threshold voltage Vtpn is lower than the second negative voltage side threshold voltage Vtnn has been described as an example. However, the magnitude relationship of the threshold voltages can be changed by, for example, changing the types of the first element, the second element, and the third element or changing the concentration ratio of the first element, the second element, and the third element.

For example, the first positive voltage side threshold voltage Vtpp may be higher than the second positive voltage side threshold voltage Vtnp. In addition, for example, the first negative voltage side threshold voltage Vtpn may be higher than the second negative voltage side threshold voltage Vtnn.

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, and a memory layer provided between the first conductive layer and the second conductive layer,
wherein the memory layer contains:
an oxide, a nitride, or an oxynitride of a first element being at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg);
a second element being different from the first element, and being at least one element selected from a group consisting of aluminum (Al), zinc (Zn), tin (Sn), gallium (Ga), bismuth (Bi), and indium (In); and
a third element being at least one element selected from a group consisting of tellurium (Te), sulfur(S), selenium (Se), and antimony (Sb),
wherein the memory layer includes a first region, a second region, and a third region, and the second region is provided between the first region and the third region,
the first region contains the second element and the third element,
the second region contains the oxide, the nitride, or the oxynitride of the first element, and contains the second element and the third element,
the third region contains the third element and contains or does not contain the second element,
a sum of an atomic concentration of the second element and an atomic concentration of the third element in the first region is greater than a sum of an atomic concentration of the second element and an atomic concentration of the third element in the second region,
an atomic concentration of the third element in the third region is higher than an atomic concentration of the second element in the third region, and
a ratio of the atomic concentration of the third element to the atomic concentration of the second element in the third region is greater than a ratio of the atomic concentration of the third element to the atomic concentration of the second element in the second region.

2. The memory device according to claim 1,
wherein the ratio of the atomic concentration of the third element to the atomic concentration of the second element in the third region is greater than a ratio of the atomic concentration of the third element to the atomic concentration of the second element in the first region.

3. The memory device according to claim 1,
wherein the atomic concentration of the third element in the first region is higher than the atomic concentration of the third element in the third region.

4. The memory device according to claim 1,
wherein the atomic concentration of the third element in the third region is higher than the atomic concentration of the third element in the second region.

5. The memory device according to claim 1,
wherein the ratio of the atomic concentration of the third element to the atomic concentration of the second element in the second region is equal to or more than 0.3 and equal to or less than 2.

6. The memory device according to claim 1,
wherein the first region further contains the oxide, the nitride, or the oxynitride of the first element.

7. The memory device according to claim 1,
wherein the third region further contains the second element.

8. The memory device according to claim 1,
wherein the third region further contains the oxide, the nitride, or the oxynitride of the first element.

9. The memory device according to claim 1,
wherein, assuming that a sum of an atomic concentration of the first element, an atomic concentration of the second element, an atomic concentration of the third element, an atomic concentration of oxygen (O), and an atomic concentration of nitrogen (N) is a total concentration, a ratio of a sum of an atomic concentration of the first element, an atomic concentration of oxygen (O), and an atomic concentration of nitrogen (N) to the total concentration in the first region is less than 50%.

10. The memory device according to claim 1,
wherein, assuming that a sum of an atomic concentration of the first element, an atomic concentration of the second element, an atomic concentration of the third element, an atomic concentration of oxygen (O), and an atomic concentration of nitrogen (N) is a total concentration, a ratio of a sum of an atomic concentration of the first element, an atomic concentration of oxygen (O), and an atomic concentration of nitrogen (N) to the total concentration in the second region is equal to or more than 50%.

11. The memory device according to claim 1,
wherein, assuming that a sum of an atomic concentration of the first element, an atomic concentration of the second element, an atomic concentration of the third element, an atomic concentration of oxygen (O), and an atomic concentration of nitrogen (N) is a total concentration, a ratio of the sum of the atomic concentration of the second element and the atomic concentration of the third element to the total concentration in the first region is equal to or more than 50%.

12. The memory device according to claim 1,
wherein, assuming that a sum of an atomic concentration of the first element, an atomic concentration of the second element, an atomic concentration of the third element, an atomic concentration of oxygen (O), and an atomic concentration of nitrogen (N) is a total concentration, a ratio of the sum of the atomic concentration of the second element and the atomic concentration of the third element to the total concentration in the second region is less than 50%.

13. The memory device according to claim 1,
wherein, assuming that a sum of an atomic concentration of the first element, an atomic concentration of the second element, an atomic concentration of the third element, an atomic concentration of oxygen (O), and an atomic concentration of nitrogen (N) is a total concentration, a ratio of the atomic concentration of the third element to the total concentration in the third region is equal to or more than 10%.

14. The memory device according to claim 1,
wherein the memory layer contains a compound of the second element and the third element.

15. The memory device according to claim 1,
wherein the first region is provided between the second region and one of the first conductive layer and the second conductive layer, and the third region is provided between the second region and the other of the first conductive layer and the second conductive layer, and
a distribution of an atomic concentration of the third element in a first direction from the one of the first conductive layer and the second conductive layer to the other of the first conductive layer and the second conductive layer has a first peak in the first region and a second peak in the third region.

16. The memory device according to claim 15,
wherein a first distance from the one of the first conductive layer and the second conductive layer to the first peak in the first direction is greater than a second distance from the other of the first conductive layer and the second conductive layer to the second peak in the first direction.

17. The memory device according to claim 15,
wherein a second distance from the other of the first conductive layer and the second conductive layer to the second peak in the first direction is equal to or less than one-fourth of a distance between the first conductive layer and the second conductive layer in the first direction.

18. The memory device according to claim 15,
wherein a third distance from the first peak to the second peak in the first direction is equal to or more than one-third of a distance between the first conductive layer and the second conductive layer in the first direction.

19. The memory device according to claim 1,
wherein the first region is provided between the second region and one of the first conductive layer and the second conductive layer, and the third region is provided between the second region and the other of the first conductive layer and the second conductive layer,
the first region is in contact with the one of the first conductive layer and the second conductive layer, and
the third region is in contact with the other of the first conductive layer and the second conductive layer.

20. The memory device according to claim 1,
wherein the first conductive layer or the second conductive layer contains at least one material selected from a group consisting of carbon, carbon nitride, tungsten, tungsten carbide, tungsten nitride, titanium, titanium nitride, tantalum, tantalum carbide, and tantalum nitride.

21. The memory device according to claim 1,
wherein the first conductive layer or the second conductive layer contains at least one material selected from a group consisting of hafnium, hafnium boride, magnesium aluminum boride, zirconium, zirconium boride, and titanium boride.

22. The memory device according to claim 1,
wherein the memory layer has a nonlinear current-voltage characteristic that a current increases at a specific threshold voltage, and the threshold voltage changes with application of a predetermined voltage.

23. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.
